(19) United States
(12) Patent Application Publication
(10) Pub. No.: US 2010/0139735 A1
(43) Pub. Date: Jun. 10, 2010

(54) Solar Energy Conversion Articles and Methods of Making and Using Same

(76) Inventor: Mark C. Anderson, Minnetonka, MN (US)

Correspondence Address: ZOLLINGER & BURLESON LTD., PO BOX 2368, NORTH CANTON, OH, 44720, US

(21) Appl. No.: 12/632,912

(22) Filed: Dec. 8, 2009

Related U.S. Application Data
(60) Provisional application No. 61/120,668, filed on Dec. 8, 2008.

(51) Int. Cl. H01L 31/042

(52) U.S. Cl. 136/244

(57) ABSTRACT

Rotationally translated PV cells exhibit enhanced efficiency relative to identical cells provided in a flat array statically arranged parallel to the plane of the earth or designed to follow the arc of the sun. A solar energy converting article that includes a shaft and a plurality of outwardly extending vanes, each of which bears a plurality of photovoltaic cells, can produce larger amounts of current than the same area of photovoltaic cells arranged in a plane. The article can be used as part of an assembly with a motor or generator.

### CROSS-REFERENCE TO RELATED APPLICATION

This application claims the benefit of U.S. provisional patent application no. 61/120,668, the entire disclosure of which is incorporated herein by reference.

### BACKGROUND INFORMATION

A photovoltaic (PV) cell emits electrons after exposure to radiative energy. Assemblies of PV cells are used to make solar modules which, in turn, can be linked in arrays.

Typical solar generators employ an array of PV cells connected in circuited arrangements to generate direct current (DC) electricity; see, e.g., U.S. Pat. Nos. 4,614,879 and 4,321,416. Unlike alternating current (AC), standard DC electrical output cannot be transformed, a characteristic which limits its use to locations relatively near its place of generation. Accordingly, much DC output of solar generators is used to power nearby devices designed to run on DC (e.g., portable calculators) or to charge storage devices such as batteries.

For solar generated DC output to be transported over a long distance or to be connected into the electrical power grid, it first must be converted into AC by means of a device such as an inverter; see, e.g., U.S. Pat. No. 4,217,633. Any such inversion process necessarily results in losses of current and, accordingly, reductions in power output efficiency.

Some solar generators are designed to create AC output directly. For example, U.S. Pat. No. 4,577,052 describes a device that directs light alternately between pairs of PN junction solar cells connected in an anti-parallel configuration. U.S. Pat. No. 6,774,299 describes a device in which a rotating shaft, actuated by a DC motor, includes a plurality of vanes on which are mounted PV cells; as the vanes rotate, the intensity of incident radiation on the panels varies, thereby developing a sinusoidal electrical voltage.

Regardless of particular form or output, solar generators are subject to the limitations of the type of PV cells/modules employed: typical cells/modules have low energy conversion efficiencies, even when optimally oriented to incident sunlight, due to inherent issues such as reflectance, thermodynamics, recombination losses, etc. Because of this inefficiency, large PV cell modules are necessary to produce modest amounts of DC electricity. Large expanses of arrays are necessary to produce moderately large currents.

Compact configurations of PV cells, modules or arrays capable of producing significant amounts of current remain highly desirable.

### SUMMARY

The methods and articles provided hereinbelow are based at least in part on enhanced efficiency of rotationally translated PV cells relative to identical cells provided in an essentially static arrangement, for example, in a flat array arranged parallel to the plane of the earth or designed to follow the arc of the sun. Rotational translation typically but not exclusively is about an axis that is perpendicular to the plane of the earth's surface. Such rotation can be in an alternating form (back-and-forth hemispherical motion) about the axis or, more commonly, in a full (360°) arc around the axis. Full rotation need not be circular and, instead, can be any of elliptical, conical, spiral, polygonal, and the like.

This efficiency enhancement is embodied in, for example, a compact article that can efficiently convert solar energy into electrical current. The article can be configured so as to include a plurality of vanes extending outwardly from a central shaft; each vane includes a plurality of PV cells that, when exposed to photons, generate DC output that can be directed away from the article in a variety of ways including, for example, toward and through the shaft. The PV cells can be linked so as to form a module and, at least in some configurations, the modules from multiple vanes can be linked to form an array. Advantageously, the article can produce significant electrical current even when proportioned so as to fill a relatively small volume. Rather than PV cell being laid flat, essentially perpendicular to the sun (i.e., ˜45°-135° from the plane of the horizon), which is the standard configuration for conventional solar collection panels, the article typically has its PV cells arranged at a non-perpendicular angle, sometimes even vertically. The article can be used as part of an assembly that additionally includes a motor, a generator (AC or DC), or both.

In one aspect is provided an article capable of efficiently converting solar energy into electrical current. The article includes a central shaft and a plurality of outwardly extending vanes, which can be arranged perpendicular to the longitudinal axis of the shaft. Some, most, or preferably all of the vanes include a plurality of PV cells on one, or preferably both, of their primary surfaces, preferably provided in the form of one or more modules. The vanes need not be physically connected to or in contact with the shaft. In one configuration, the shaft can include annular brackets designed to engage with or otherwise retain the vanes; although such brackets can be integral with the shaft, the parts typically are produced separately and assembled at the time of use. In other configurations, each vane can be connected to the central shaft through a radially extending arm or through an adjustable connecting assembly to a linear bracket (e.g., one disposed parallel to the primary axis of the shaft) adapted to engage with an end edge of a vane.

The article can be housed in a chamber designed or adapted to protect the article from dust, rain, wind, and the like. The chamber can be provided with an interior pressure less than that of the atmosphere outside the chamber. For ease of assembly, the components of the chamber can be provided separately and assembled after the article is provided.

In another aspect is provided an assembly that includes a rotational solar energy converting article and a generator (AC or DC). The shaft of the assembly is in electromagnetic communication with the generator such that photovoltaically created electric current translates to the generator. Advantages of this type of assembly include integral powering of the assembly, an ability to control the current produced by the rotating assembly and, in the case of AC, elimination of the need for an inverter.

In yet another aspect is provided an assembly that includes a rotational solar energy converting article and a motor. The rotating shaft of the assembly is in electromagnetic communication with the motor. The motor can be used to initiate rotation of the article. (Unless surrounding context implies otherwise, the term “generator” means a machine that converts mechanical energy into electrical energy and “motor” means a machine that converts electrical energy into mechanical energy.)

In a further aspect is provided a method of generating DC electrical output from solar-origin energy. The method involves providing PV cells, modules or arrays on a support that can rotationally transport them through an arc of at least 180°, preferably a full 360°, while they generate DC output. One configuration adapted for use in this method is an article involving a central rotatable shaft with outwardly extending PV cell-, module- or array-bearing vanes.

In a still further aspect is provided a method for producing electrical energy from a renewable source in proximity to a utility system or to an AC user. The method involves providing electromagnetic communication between a device in which PV cells, modules or arrays are permitted to spin or rotate and a utility system component involved in use or delivery such as, for example, an electrical utility pole, telephone pole, or the like, which at least in certain embodiments can be in proximity to the AC user. The device, which often is provided in a form that constitutes a volume of from ˜0.1 to ˜5 m³, more commonly from ˜0.2 to ˜3 m³, transforms, solar-origin energy into electricity at a distance of no more than a meter or two from the component. In some configurations, the device can be affixed to the utility system component. This method can provide a convenient way to locally produce energy from a renewable (or non-consumed) natural source.

In a yet still further aspect is provided a method for producing electrical energy from a renewable source in proximity to a vehicle. The method involves providing electromagnetic communication between the motor of the vehicle and a device in which PV cells, modules or arrays are permitted to spin or rotate. The device transforms solar-origin energy into electricity while affixed (permanently or removably) to the vehicle or some structure connected thereto (e.g., a trailer).

Other aspects will be apparent to the ordinarily skilled artisan from the accompanying figures and the more detailed description that follows.

### BRIEF DESCRIPTION OF THE DRAWINGS

Illustrative configurations set forth in the description that follows are shown in the drawings, where similar numbers refer to similar parts or features. None of the figures is to scale.

FIG. 1 is a perspective view of one configuration of a solar energy converting article according to the present invention.

FIG. 2 is a perspective view of another configuration of a solar energy converting article according to the present invention.

FIG. 3 is a side view, portions broken away, of a connecting assembly for securing a radial vane to a shaft other than the ones portrayed in FIGS. 1 and 2.

FIG. 4 is a top perspective view of yet another configuration of a solar converting article according to the present invention.

FIG. 5 is a bottom perspective view of an assembly which employs the article shown in FIG. 4.

FIG. 6 is a top perspective view of the assembly from FIG. 5.

FIG. 7 is a perspective view of another configuration of an assembly in which the article from FIG. 1 is shown in conjunction with a generator, stand, and optional protective cover.

FIG. 8 is a close-up side view, portions broken away, of a portion of the assembly of FIG. 7.

FIG. 9 is a partial close-up top view, portions removed, of a portion of the assembly of FIG. 7.

FIG. 10 is a top perspective view of another configuration of an assembly depicted in an exemplary end-use environment.

### DETAILED DESCRIPTION OF ILLUSTRATIVE EMBODIMENTS

The following description is provided to explain and exemplify the efficiency enhancement provided by rotational translation of PV cells. It describes exemplary configurations and methods of operation. The appended claims define the inventions in which exclusive rights are claimed, and they are not intended to be limited to particular embodiments shown and described.

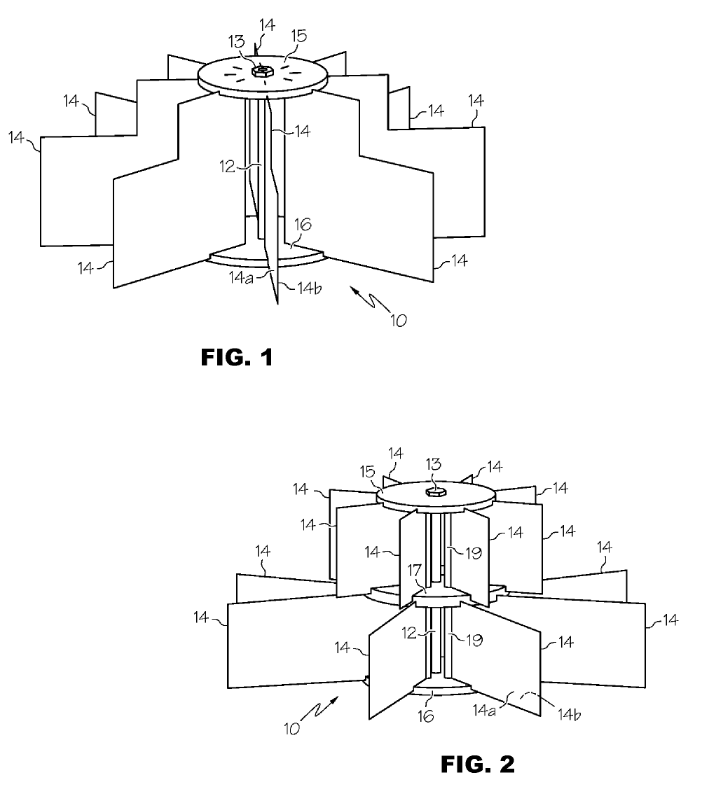

Depicted in FIGS. 1, 2 and 4 is solar energy converting article 10 which generally includes shaft 12 and a plurality of outwardly extending vanes 14. In these versions, each vane 14 extends radially from shaft 12, although alternative arrangements, e.g., tangential, parallel to a radius, etc., are possible. As depicted in these versions, shaft 12 commonly is vertically disposed relative to the ground or other supporting surface.

Shaft 12 typically need not present a solid cross-section but, instead, can be at least partially hollow. Shaft 12 can be provided from a variety of materials including, but not limited to metals such as iron, copper, aluminum, and titanium; alloys such as stainless steel, bronze, and brass; carbon fiber composites; and any of a variety of plastics or ceramics.

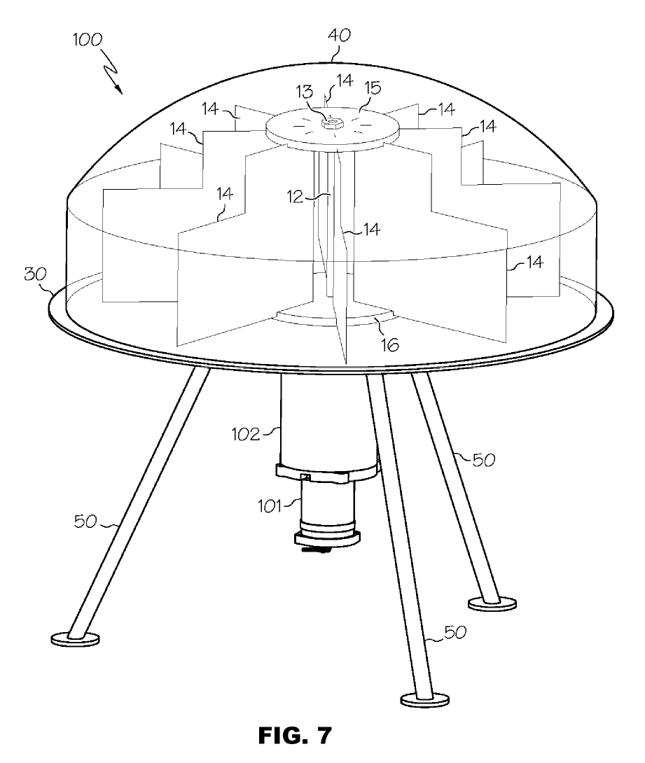

The number of vanes that can be employed in article 10 can vary widely, generally ranging from as few as two to several dozen. While each of the configurations of article 10 shown in the figures employs an even number of vanes, odd numbers of vanes are contemplated. Each vane 14 is depicted with a stepped configuration in FIG. 1, with generally square (top half) and rectangular (bottom half) configurations in FIG. 2, and with a rectangular configuration in FIG. 4. The vane geometries depicted in the various figures are exemplary and not intended to be limiting; for example, vanes that are curved or have an irregular polygonal shape can maximize the surface area available for attachment of PV cells, modules or arrays when article 10 is designed for use in an assembly involving a protective cover (as discussed below in connection with FIG. 7 below).

Each vane 14 is presented as having generally flat primary surfaces, with those in FIGS. 1 and 2 disposed parallel to the longitudinal axis of shaft 12 (depicted as being vertically disposed) and those in FIG. 4 disposed in a somewhat biased, angled fashion, i.e., not perpendicular to the longitudinal axis of shaft 12.

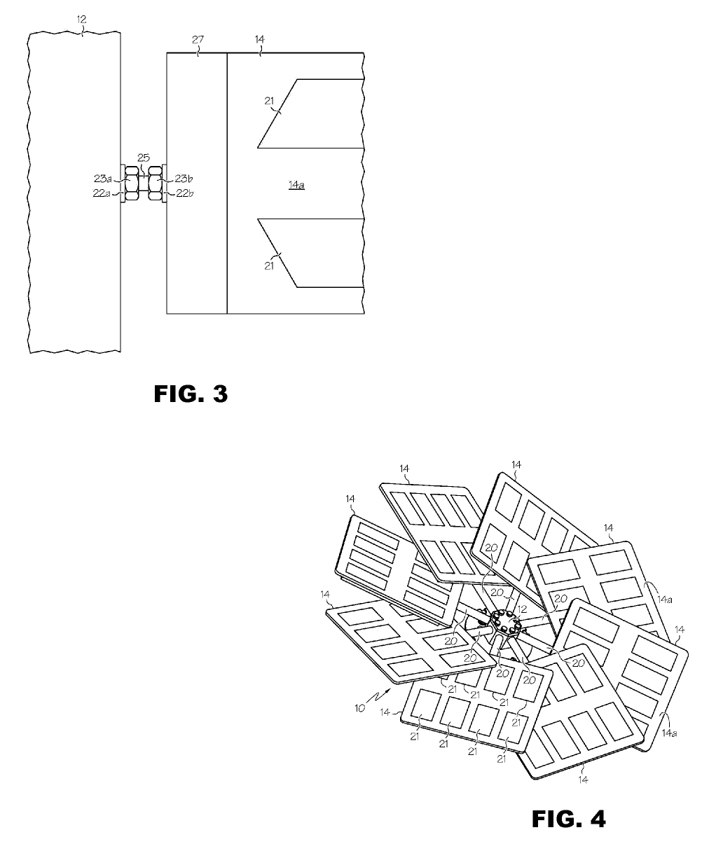

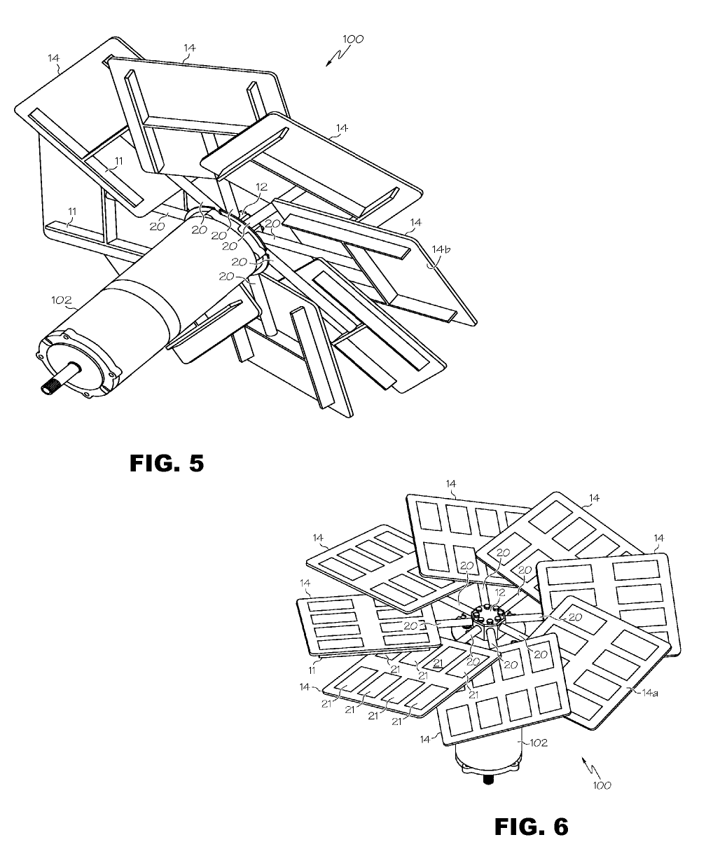

None of the vanes shown in the figures physically contacts shaft 12. In FIG. 1, each vane 14 is fitted in complementary slots provided in top bracket 15 and bottom bracket 16; in FIG. 2, each is fitted in complementary slots provided in top bracket 15 or bottom bracket 16 and intermediate bracket 17, as well as optional vertical support 19 in FIG. 3; in FIG. 4, article 10 employs an alternative attachment mechanism, with each vane 14 being affixed to a corresponding bracket 11 (visible in FIGS. 5 and 6) disposed at the distal end of radial arm 20, with each radial arm extending toward and attaching to shaft 12. In the configurations depicted in FIGS. 1 and 2, top bracket 15 can be secured to shaft 12 by means of fastening device 13, a non-limiting example of which is a lock washer.

The foregoing configurations are exemplary and not intended to be limiting. For example, FIG. 3 depicts an alternative securing configuration which permits vane 14 to be set at any of a variety of desired angles. In FIG. 3, only one vane 14 bearing PV cells 21 is shown; other, similar vanes have been omitted for clarity. Vane 14 is secured in bracket 27, which is depicted as essentially parallel to shaft 12, by friction fit, adhesive, adjustable tightening hardware (not shown), or any of numerous other means. In turn, bracket 27 connects to shaft 12 via rod 25. Hex nuts 23a and 23b are shown as being spaced from, respectively, shaft 12 and bracket 27 by optional annular washers 22a and 22b. Bracket 27 (and accordingly vane 14) can be rotated away from the vertical plane by loosening hex nut 23b, rotating bracket 27 (and accordingly vane 14) to the desired angle, and retightening hex nut 23b.

Each of the figures depicts a configuration in which separate vanes are attached to a unitary shaft. Configurations where pre-made subassemblies in which a vane and a corresponding portion of a shaft (e.g., the portion corresponding to an arc that equates to 360/n with n being the number of vanes employed) are assembled (e.g., by snap- or slide-fitting) so as to form a shaft also are contemplated.

Each vane includes two primary surfaces, identified as 14a and 14b. Each primary surface preferably bears an array of PV cells 21, graphically depicted in the embodiments shown in FIGS. 3 and 4 but omitted from the other figures for the sake of simplicity and clarity (with regard to the other components of the article). PV cells can be disposed over most (e.g., at least 50%, at least 75% or even at least 80%) of each primary surface. Each vane 14 typically will bear one or more modules of PV cells, although this feature is not mandatory.

The size of each vane (i.e., the area of primary surfaces 14a and 14b) is not particularly limited. Depending on the particular end use application, this size can range from a few square centimeters to several square meters. Because the amount of power needed for a particular application usually is known in advance, this information, in combination with the efficiency ratings of the particular PV cells employed, can be used to determine the amount of current needed and, in turn, the total amount of vane area required.

A variety of types and constructions of PV cells can be employed, although those which can be provided in the form of a flexible strip or film have been found to be advantageous because of their light weight. Commercial suppliers of PV cells and arrays include BP Solar USA (Frederick, Md.) and Iowa Thin Film Technologies Inc. (Ames, Iowa). Where higher efficiencies are desired, semiconductors other than silicon-type can be preferred; some of these are capable of being activated by or energized with, in addition to photons, IR, near-IR, UV, and other types of solar-origin energy. Suppliers of highly efficient PV cells and arrays include Emcore Corp. (Albuquerque, N. Mex.) and Spectrolab, Inc. (Sylmar, Calif.).

Vanes 14 typically are provided from a lightweight material such as any of a variety of plastics, although other materials also can be used. In some embodiments, vanes 14 can be provided from one or more optically transparent materials, e.g., polycarbonate, PMMA, etc., to decrease overall reflectance or non-generating absorbance of the article, thereby increasing the number of photons that can reach a PV cell at any given point in the orbital path of vanes 14 as shaft 12 rotates. Although not required, the shaft and/or brackets also can be made from optically transparent materials. Regardless of whether the brackets employed in the embodiments shown in FIGS. 1-3 are optically transparent, they preferably are provided from materials that are not electrically conductive and that have a relatively small thermal expansion coefficient (which can help to ensure secure engagement with vanes 14 during operation).

The PV cells, modules or arrays can be integrated with the vanes in a variety of ways, although optically transparent adhesives (including hot melts, air curable, PSAs, etc.) are relatively easy and effective. Alternatively, each vane can be provided as a group of components, some of which can be machined or formed so as to be adapted to receive predetermined sizes and/or configurations of PV cells and other, complementary components designed to secure the PV cells and mate (optionally in a snap-fit manner) with the first types of components. Another such option involves two or more lamina mechanically or adhesively secured so as to provide PV cells in back-to-back arrangement and sharing a common ground.

Vanes that include one or more integrated arrays also are contemplated.

In the configurations of the article and assembly shown in the figures, electrical connections between the PV cells on a single vane, as well as the connections between vanes, have been omitted so as to permit the other elements of the article and assembly to be rendered more clearly. Connecting PV cells to form modules, using either series or parallel connections, and connecting vanes (in either series or parallel) both are within the capabilities of the ordinarily skilled artisan to envision, so written description of these connections is omitted for the sake of brevity.

In addition to the central shaft configurations shown in the figures and described above, the ordinarily skilled artisan can envision other ways in which PV cells, modules or arrays can be arranged in a manner that permits rotational translation, either full or partial, thereof. Non-limiting examples include a rotating dome, drum or inflatable support; reciprocating paddles or other supports (which can be driven by any of a variety of mechanical or electrical mechanisms and which can travel through an arc of anything less than 360°); a support that traverses a circuit on a track; and a rotating belt or track. Additionally, two or more of these alternatives can be used in combination or one or more of these alternatives can be used in combination with the central shaft designs exemplified in the figures.

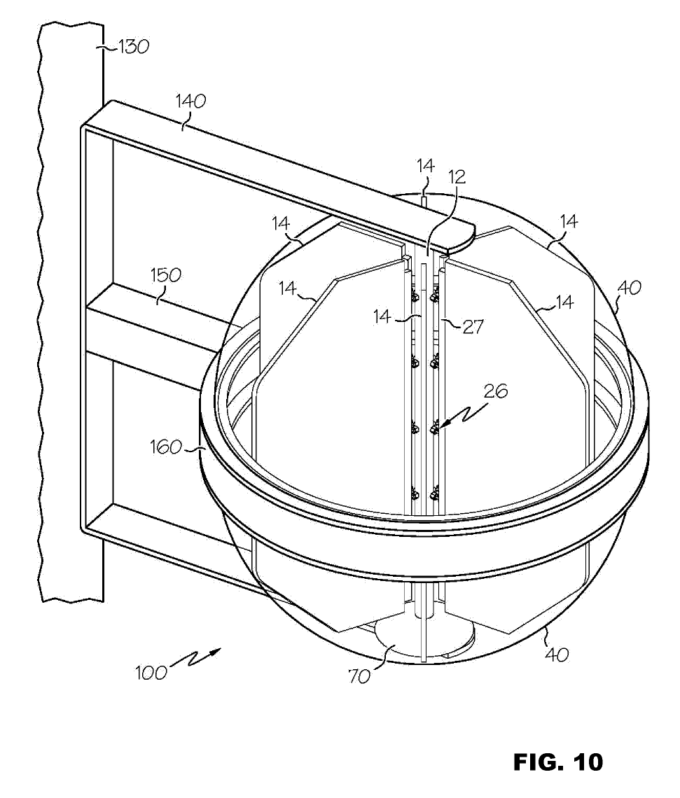

Referring to FIG. 4 (also visible in FIG. 6), each radial arm 20 is part of a unitary assembly that includes shaft 12. Because the version of article 10 shown in FIG. 4 includes radial arms affixed to a central shaft, it typically is provided as part of unitary assembly 100, as shown in FIGS. 5 and 6. Conversely, configurations of article 10 such as those employed in FIGS. 1 and 2 (as well as one employing the attachment arrangement shown in FIG. 3 and the one employed in the assembly of FIG. 10), which also can be provided as part of a unitary assembly such as that shown in FIG. 7, also permit the shipping of individual component pieces or partially assembled portions to an intended use site prior to being assembled and operationally connected to other components so as to form such an assembly.

In FIGS. 5 to 7 is depicted generating assembly 100 which includes a solar energy converting article, such as has been described above, in electromagnetic communication with generator 101 (partially visible in FIG. 7), which typically is protected by housing 102. The manner in which article 10 connects to and electromagnetically communicates with generator 101 (or motor) is described in more detail below.

An electrical generator, often called a dynamo, translates motion (in the present case, rotational motion of an axle attached to a commutator) into electrical current through the powering of an electromagnet(s) in operational proximity to a field magnet. The components, arrangement and internal operation of dynamos are familiar to the ordinarily skilled artisan and, accordingly, are not described in detail here.

The configuration of assembly 100 shown in FIGS. 5 to 7 thus employs rotational motion of shaft 12 to power generator 101 which, in turn, provides current. The speed at which shaft 12 rotates is not particularly limited, with speeds of several thousand rpm being feasible. Operational rotational speeds typically range from ˜5 to ˜5000 rpm, more typically ˜10 to ˜1000 rpm, commonly from ˜20 to ˜750 rpm, and more commonly from ˜30 to ˜500 rpm.

A wide variety of generator models can be used in assembly 100, and the particular type and model for a particular assembly can be selected based on the type of electrical output (AC or DC) and amperage desired. One supplier of a variety of brush and brushless generators is Minnesota Electric Technology, Inc. (Mankato, Minn.).

A motor can be substituted for generator 101 to provide an assembly of similar construction but essentially opposite operation. Electrical current (from an external source or from DC output of PV cells on vanes 14 as they become energized with electrical current flowing from the article to the motor through connection wires 60) is employed to create electromagnet(s) which, together with a field magnet, result in rotational motion of an axle to which is attached a commutator. Rotation of the axle causes shaft 12 of the article, which is in operational communication (e.g., mechanically via pulleys, belts, gears, etc., magnetically, or the like) with the axle, and vanes 14 attached thereto to rotate. The speed of this rotation is not particularly limited, with the rotational velocity ranges set forth above being applicable here as well.

Rotation of these vanes is one manner of achieving the enhanced efficiency of rotationally translated PV cells mentioned previously. Assembly 100 provides rotational translation about an axis that, in typical operation, is perpendicular to the plane of the earth's surface. This rotation commonly involves a 360° arc around the axis, although a reciprocating, hemispherical motion about the axis also is possible through proper motor selection.

For additional details on motors, the interested reader is directed to any of U.S. Pat. Nos. 3,450,907, 3,760,209, 4,414,481, 4,820,948, and 5,334,897, as well as more recent patent documents citing these. Non-limiting examples of types of motors that can be employed in assembly 100 include wheel hub motors and spindle motors (such as those employed to rotate hard disk platters in computers).

The configuration of assembly 100 in FIG. 7 includes the solar energy converting article depicted in FIG. 1 in electromagnetic communication with generator 101 (or motor), with the article being protected by a chamber formed by optional protective cover 40 resting on base 30 supported by optional legs 50. This arrangement can provide additional benefit where assembly 100 is used in areas subject to accumulations of snow, falling leaves, and the like.

Base 30 is shown in FIG. 7 as opaque and substantially flat, although neither feature is required. Providing base 30 with some concavity and/or reflectivity might result in increased efficiency of the solar energy converting article. Reflectivity can be provided by forming base 30 from a metal or a laminate having as its uppermost lamina a layer provided from a metal foil, metalized film, etc. Concavity can be provided from any of a variety of molding or stamping techniques and even post-formation manipulation.

Where a protective cover 40 is employed, it can be designed to rest on base 30 and accordingly, the perimeter of base 30 generally will extend at least somewhat beyond that of protective cover 40. Although protective cover 40 is shown as rounded or hemispherical in shape, these are by way of example only. Additionally, while protective cover 40 often is provided solely from an optically transparent material, it may be designed or adapted to include lenses, multilayer films, coatings, filters, etc., to magnify, focus, modify (e.g., phase shift), etc., available light.

A protective chamber can be formed by applying protective cover 40 over article 10 onto base 30. The pressure of the chamber in which solar energy converting article 10 operates can be reduced, i.e., at least a partial vacuum can be created in the chamber. Reducing the air resistance encountered by vanes 14 might positively affect the efficiency of the rotation of the article. One way in which evacuation of the protective chamber can be accomplished is by providing in base 30 a vacuum connection fitting (not shown) into which a vacuum line can be attached and then removing a desired volume of air from the chamber.

Where assembly 100 from FIG. 7 is not provided in assembled form, it can be assembled by an end user. A shaft, rod or axle of generator 101 (not shown) or motor, which extends through housing 102, can engage with shaft 12, inserted through bottom bracket 16 and base 30. Vanes 14 can be engaged with brackets 15 and 16, and fastening device 13 is applied over upper bracket 15 and engaged with shaft 12.

Alternatively, shaft 12 can be provided as part of generator 101 (or motor), an arrangement which avoids the need for complementary pieces associated with the article and the generator from needing to be assembled and to remain engaged during operation.

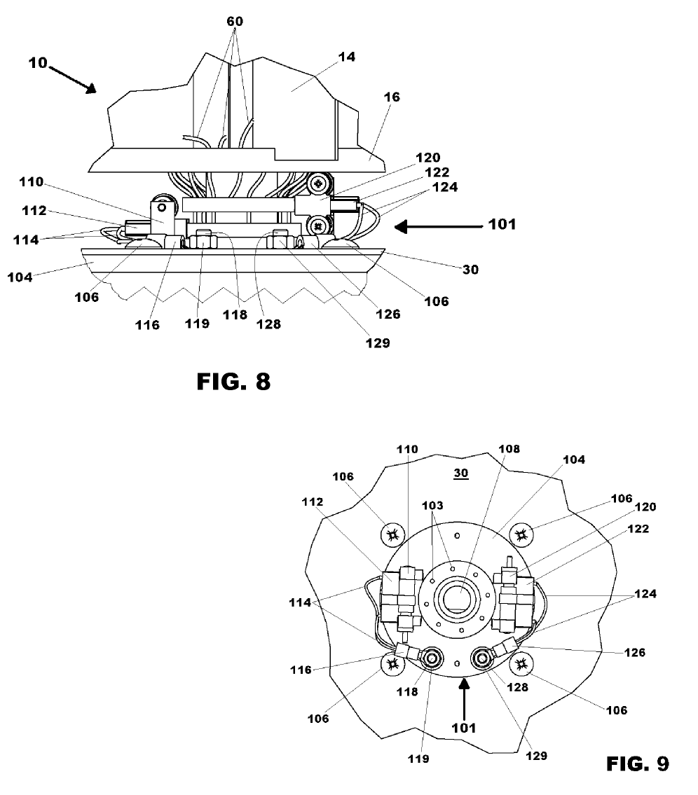

Electromagnetic communication between solar energy converting article 10 and generator 101 (or motor) is described with reference to FIGS. 8-9 which provide an exemplary configuration which is not intended to be limiting and, instead, is intended to provide to the ordinarily skilled artisan an exemplary environment in which article 10 can be used, as well as an exemplary electromagnetic connection between article 10 and generator 101.

Each vane 14, individually or collectively via inter-vane electrical connections (e.g., wiring), is electrically connected to generator 101 through one or more connection wires 60. As the PV cells, modules or arrays on one or more vanes convert incident photons into electricity, current flows from the PV cells (through unshown semiconductor contacts) to the respective connection wire(s) that electrically communicate with generator 101 via connection points 103 which, in turn, electrically communicate with those portions of generator 101 which power the armature component and/or create magnetism in the field component, by which the generator axle or shaft (rotor), as well as shaft 12 of the article, is caused to rotate. As briefly summarized above, rotation through a magnetic field produces current, either AC or DC depending on the particular configuration and operation of the generator (e.g., whether a commutator is included), which can be transmitted away from assembly 100 and used or stored. Current output of such generators is well understood, easy to calculate in advance, easy to regulate, etc.

In FIGS. 8-9, a portion of generator 101 is shown extending above the plane defined by base 30 but below the plane of lower bracket 16, which is visible in FIG. 7 but which, along with shaft 12, vanes 14, upper bracket 15, and fastening device 13 have been broken away from the view shown in FIG. 8. The structure and operation of the portions of generator 101 below the plane of base 30 (and inside housing 102 seen in FIGS. 5 to 7) are not described herein due to their familiarity to ordinarily skilled artisan, as set forth above.

The components of generator 101 seen in FIGS. 8 and 9 likewise are familiar to the ordinarily skilled artisan but are summarily described here so that the environment in which article 10 operates can be more easily envisioned. Generator end bell 104 fits into and/or engages with an opening in base 30, while mounting screws 106 ensure that generator 101 remains secured to article 10. The ordinarily skilled artisan can envision several other techniques for engaging and securing these components.

Generator axle 108 can be seen extending slightly above the plane of base 30 in the view shown in FIG. 9. As suggested previously, other configurations are possible. For example, shaft 12 can be provided so that it extends into and acts as part of generator 101 or, conversely, axle 108 can extend farther and also act as the shaft for article 10.

In the particular generator shown in FIGS. 8 and 9, the portion that extends above the plane of base 30 includes the electrical converting and transmission components, specifically, brush unit housings 110 and 120, brushes 112 and 122 (typically carbon brushes, although other materials also can be used), brush shunts 114 and 124 which typically are provided as insulated wires, brush shunt lugs 116 and 126, generator power terminals 118 and 128, and generator power terminal stud nuts 119 and 129. Brush shunts 114 and 124, respectively, are connected to generator power terminals 118 and 128 and secured by, respectively, stud nuts 119 and 129. While the generator shown in FIGS. 8 and 8 is a brush-type model, brushless types of commutators can be used.

Conveyance of electrical current from power terminals 118 and 128 to an electrically powered device, a battery or, in the case of AC, the power grid can be accomplished through a wide variety of known connections and techniques.

If a motor is substituted for a generator in the assemblies shown in FIGS. 5 to 7, electrical connectivity is only slightly altered. A small amount of current generated by energized PV cells of the article can be directed to and powers the motor to initiate and maintain rotation at the desired speed. (Where the motor receives power, e.g., electrical current, from a separate source, the solar energy converting article need not be in electrical communication with the motor.) The majority of current generated by the PV cells can be directed away from assembly 100 in any of a variety of ways including, but not limited to, electrical connections directed into and through shaft 12 (where the shaft is hollow) or frictional (brush or brushless) connection(s) located at any of a variety of points above or below the arc of the vanes. DC output from assembly 100 can be conveyed to power an electrically powered device, to charge a battery or other storage device, or, after inversion, to the power grid at any necessary or specified voltage. Advantageously, as most easily envisioned in connection with FIG. 10 (discussed below), the latter option can occur proximal to the point of intended use without involvement of a high voltage transmission line between a remote point of generation and point of use.

Referring again to FIG. 7, assembly 100 is sized and configured so that it can be used in a wide variety of environments and attached or affixed to a wide variety of objects. With or without optional legs 50, the assembly can be positioned on the roof of or adjacent to a building to be powered. Conveniently, where assembly is configured for AC electrical output, the current can be used directly without the need for an inverter. Depending on the size and efficiency of assembly 100, the entire electrical power requirements of the building can be provided from one or a plurality of assemblies and, where more than the needed amount of electricity is provided, the excess can be fed directly into the power grid.

Assembly 100 also can be configured to be used in conjunction with, for example, a motorized vehicle. The vehicle can be configured to run in whole or in part on DC electricity, and the assembly can be configured for DC electrical output. Again, depending on the size and efficiency of assembly 100, the entire electrical power requirements of the vehicle can be provided from the assembly. Excess current can be used to charge or recharge a battery in the vehicle.

The preceding two uses are intended to be exemplary and, accordingly, are not limiting; the ordinarily skilled artisan is able to extend these to a variety of other possible environments.

The configuration of assembly 100 in FIG. 10 includes another configuration of a solar energy converting article in electromagnetic communication with a motor (hidden by motor cover 70), with the article being protected by a chamber formed by protective cover 40 which engages with annular frame 160. This configuration includes a protective cover that has two essentially hemispherical halves, although the ordinarily skilled artisan can envision a unitary cover that encases the solar energy converting article and rests upon a support, thereby eliminating the need for a frame.

The motor operationally engages and turns shaft 12 of the solar energy converting article. As with other configurations of the solar energy converting article, rotation of shaft 12 can vary widely from a fraction of rotation per second to several rotations per second. Most types of motors will permit varying rotational speed, thus permitting real-time variation of shaft speed.

Rotation of shaft 12 causes each vane 14 to rotate, in turn causing PV cells (not shown for reasons explained above) borne thereon or therein to pass through an arc. Each vane 14 is attached to shaft 12 similarly to that which is described above in connection with FIG. 3, specifically, via bracket 27 linked through connecting assembly 26 (which can employ components such as the spacers and hex nuts shown above in connection with FIG. 3). PV cells, modules or arrays on the vanes as well as intra- and inter-vane electrical connections, have been omitted so as to permit other elements of the article and assembly to be presented more clearly. Attachment and connection of these unshown elements can be accomplished in a manner similar to those described earlier in this description.

The motor of assembly 100 can be located at other positions within or without assembly 100 and can be powered from current drawn from PV cells, modules or arrays on vanes 14, from a separate self-contained source (e.g., rechargeable battery) or from a separate line running from vertical support 130. Additionally, more than one motor can be employed and, in such cases, a synchronizing device or mechanism typically also can be employed.

As shown, assembly 100 is supported above and below by horizontal arms of C-bracket 140. Assembly 100 can connect to this type of support by any of a number of mechanisms. In the particular configuration shown in FIG. 10, either the top or bottom arm of C-bracket 140 can be used to attach the motor (unshown) while also providing optional electrical communication between the motor and vertical support 130. Bracket 140 can be attached to vertical support 130 (e.g., utility pole) by any of a number of mechanical or adhesive techniques.

In addition to the bracket, assembly 100 can be connected to vertical support 130, portions broken away, via optional conduit 150. While electromagnetic communication of assembly 100 to utility components (unshown) also attached to vertical support 130 can be accomplished through wiring in or on bracket 140, optional conduit 150 can provide additional protection for current running from a utility component to the motor (unless some current from assembly 100 is diverted for that purpose) or from assembly 100 to one or more utility components (e.g., transformers, wires, etc.). Optional conduit 150 also can provide a convenient location for placement of an inverter, although many such devices are sufficiently small to be able to located within assembly 100, on bracket 140 or elsewhere on vertical support 130.

Assembly 100 can be sized to meet a wide variety of current or voltage requirements while retaining the ability to be mounted to a vertical support such as a utility pole. When vertical support 130 is a utility pole, an assembly such as the one depicted in FIG. 10 permits AC generation (via inversion) extremely close to the point of use. In other words, in addition to acting as supports for power lines running to other utility poles, many utility poles have power lines running to one or more nearby buildings. Being able to generate electricity at a utility pole close to the point of usage is highly desirable because transmission losses are minimized, a factor that can outweigh any efficiency losses incurred by passing DC through an inverter to create AC.

Operation of assembly 100 can be monitored, typically from a remote location. Electrical output can be measured and reported, either through a hard-wired or wireless connection, to a monitoring point or facility which, in turn, can adjust operation parameters so as to account for load demands, increase efficiency, or the like. The monitoring also can be used provide data useful in invoicing an electrical utility, its customer(s) or both.

Each of the foregoing articles and assemblies, as well as alternative devices set forth above, can be used to generate electrical output from solar-origin energy via PV cells, modules or arrays disposed on or in one or more supports that can rotationally transport them through an arc while they generate DC output. The arc typically will be at least 15°, at least 30°, at least 45°, at least 60°, at least 75°, at least 90°, at least 105°, at least 120°, at least 135°, at least 150°, at least 165°, at least 180°, or at least the corresponding complementary angle between 180° and 360°. The rotational transport of the PV cells, modules or arrays typically involves some type of reciprocating motion unless they are transported in a full circle.

The following table summarizes in list form the terms and phrases used to identify suitable parts and materials.

TABLE 1
List of reference symbols

| Number | Description |
|---|---|
| 10 | solar energy converting article |
| 12 | shaft |
| 13 | fastening device |
| 14 | vane |
| 15 | top bracket |
| 16 | bottom bracket |
| 17 | intermediate bracket |
| 19 | vertical support |
| 20 | radial arm |
| 21 | PV cell |
| 22 | washer |
| 23 | hex nut |
| 25 | rod |
| 26 | connecting assembly |
| 27 | bracket |
| 30 | base |
| 40 | protective cover |
| 50 | legs |
| 60 | solar panel connection wires |
| 70 | motor cover |
| 100 | electrical power generating assembly |
| 101 | generator |
| 102 | generator housing |
| 103 | connection wire connection points |
| 104 | end bell |
| 106 | mounting screws |
| 108 | axle |
| 110 | brush unit housing |
| 112 | brush |
| 114 | brush shunts |
| 116 | brush shunt lug |
| 118 | generator power terminal |
| 119 | power terminal stud nut |
| 120 | brush unit housing |
| 122 | brush |
| 124 | brush shunts |
| 126 | brush shunt lug |
| 128 | generator power terminal |
| 129 | power terminal stud nut |
| 130 | vertical support |
| 140 | bracket |
| 150 | conduit |
| 160 | annular frame |

The foregoing description has employed certain terms and phrases for the sake of brevity, clarity, and ease of understanding; no unnecessary limitations are to be implied therefrom because such terms are used for descriptive purposes and are intended to be broadly construed. The relevant portion(s) of any patent or publication specifically mentioned in the foregoing description is or are incorporated herein by reference.

The foregoing configurations and methods have been presented by way of example only. Certain features of the described configurations and methods may have been described in connection with only one or a few such configurations or methods, but they should be considered as being useful in other such configurations or methods unless their structure or use is incapable of adaptation for such additional use. Also contemplated are combinations of features described in isolation.

That which is claimed is:

1. An article useful for converting solar-origin energy to electricity, said article comprising a central, vertically disposed shaft and a plurality of outwardly extending vanes wherein at least some of said vanes comprise one or more photovoltaic cells, modules or arrays on or along at least one their primary surfaces.

2. An electrical generating assembly comprising the article of claim 1 in electromagnetic communication with an electrical generator, said article being capable of powering said electrical generator.

3. An electrical generating assembly comprising the article of claim 1 and a motor, said shaft being in operational engagement with an axle of said motor.

4. A method of converting solar-origin energy, said method comprising rotationally transporting through an arc a support on which is disposed one or more photovoltaic cells, modules or arrays while said photovoltaic cells, modules or arrays generate DC electrical output.

5. The method of claim 4 wherein said arc is at least 180°.

6. The method of any of claim 4 wherein said support comprises a vane operationally engaged with a rotatable shaft.

7. The method of claim 6 wherein said shaft is in operational engagement with a motor adapted to rotationally impel said shaft.

8. The method of claim 7 further comprising inverting said DC electrical output to AC electrical output.

9. The method of claim 8 wherein both the rotational transportation and inversion steps are performed within two meters of a utility system component.
